(19) United States
(12) Patent Application Publication
(10) Pub. No.: US 2017/0025561 A1
(43) Pub. Date: Jan. 26, 2017

(54) MANUFACTURING METHOD OF SOLAR CELL AND SOLAR CELL

(71) Applicant: Mitsubishi Electric Corporation, Tokyo (JP)

(72) Inventor: Hayato KOHATA, Tokyo (JP)

(73) Assignee: Mitsubishi Electric Corporation, Tokyo (JP)

(21) Appl. No.: 15/301,653

(22) PCT Filed: Apr. 4, 2014
(86) PCT No.: PCT/JP2014/060012

§ 371 Date: Oct. 3, 2016

(51) Int. Cl. H01L 31/068; H01L 31/18; H01L 31/0224

(52) U.S. Cl. CPC H01L 31/068; H01L 31/022425; H01L 31/1804

(57) ABSTRACT

When a high-concentration diffusion layer is formed in part of a first surface of a substrate in which a diffusion layer of the light receiving surface is formed, the thermal oxidation is performed in a state where a diffusion source is formed, thereby introducing the impurity in the outermost surface of the diffusion layer of the light receiving surface into a thermal oxide film. Consequently, the outermost surface of the diffusion layer of the light receiving surface has an impurity concentration lower than that on the inner side.

### FIELD

The present invention relates to a manufacturing method of a solar cell and a solar cell.

### BACKGROUND

In conventional crystalline silicon solar cells, the diffusion concentration and depth of a diffusion layer on the light receiving surface side are factors in determining the surface recombination velocity and the recombination velocity in the diffusion layer; therefore, they significantly affect the conversion efficiency. The impurity concentration dependence of the diffusion layer is such that an increase in concentration causes the recombination velocity to increase and, in contrast, causes the contact resistance between the diffusion layer and the electrodes and the surface conductivity to decrease, which reduces the internal resistance loss. Diffusion layers of solar cells have been designed taking into consideration the balance between recombination and the internal resistance loss.

In order to increase the efficiency of solar cells, a structure is proposed in which the portion under electrodes has a high concentration and the light-receiving-surface portion other than the portion under electrodes has a low concentration. This structure is referred to as a selective diffusion layer (selective emitter) structure. This structure, however, makes the manufacturing process of solar cells complicated.

There is a description, for example, in Patent Literature 1, of a method of forming a light-receiving-surface-portion diffusion layer, then printing a paste containing an impurity on the electrode forming portion, and then performing a heat treatment again. Moreover, a technology is proposed, for example, in Patent Literature 2 in which doping pastes having different impurity concentrations are printed and a selective diffusion layer is then formed by performing a single heat treatment. Furthermore, for example, disclosed are a technology in which an impurity is diffused into the entire surface in accordance with the impurity concentration of an electrode forming portion and the outermost surface of a diffusion layer excluding the electrode forming portion is removed by etching and a technology in which the entire diffusion layer excluding an electrode forming portion is removed and thermal diffusion is then performed at a low concentration.

### CITATION LIST

### Patent Literature

Patent Literature 1: Japanese Patent Application Laid-open No. 2004-281569

Patent Literature 2: Japanese Patent Application Laid-open No. 2004-273826

### SUMMARY

### Technical Problem

Although the method in Patent Literature 1 is simple in process, autodoping sometimes occurs during the second heat treatment. In the method in Patent Literature 2, it is necessary to, for example, perform a doping paste application step many times and thus perform mask alignment; therefore, the manufacturing process is complicated. As described above, the above conventional technologies have a problem in that it is difficult to optimize the diffusion layer on the light-receiving-surface side.

The present invention has been achieved in view of the above and an object of the present invention is to increase the efficiency of a solar cell by reducing the surface concentration of the light receiving surface and increasing the impurity concentration under the electrodes while facilitating the control of the concentration of the diffusion layer.

### Solution to Problem

In order to solve the above problems and achieve the object, an aspect of the present invention is a manufacturing method of a solar cell including: a step of preparing a first-conductivity-type semiconductor substrate that includes a first surface constituting a light receiving surface and a second surface opposed to the first surface; a first diffusion step of forming a second-conductivity-type diffusion layer in the first surface; a second step of forming a film that includes a second-conductivity-type diffusion source on part of the first surface of the semiconductor substrate in which the second-conductivity-type diffusion layer is formed; a third step of forming a high-concentration diffusion layer by diffusion from the diffusion source, by performing a heat treatment in an oxidizing atmosphere on the semiconductor substrate on which the diffusion source is formed; a step of forming a first electrode on the high-concentration diffusion layer; and a step of forming a second electrode on the second surface.

### Advantageous Effects of Invention

According to the solar cell in the present invention, by performing the thermal oxidation on the surface, the outermost surface that contains many defects is introduced into the oxide film and an impurity is diffused into the electrode-forming portion from the doping paste during the oxidation treatment; therefore, the resistance of the electrode-forming portion can be reduced. Consequently, the contact resistance between the electrode-forming portion and the electrodes can be significantly reduced, which is effective in increasing the efficiency. The oxide film formed during the oxidation has a high transmittance and thus causes less absorption loss. Moreover, thermal oxide films typically have a low interface state density; therefore, a passivation effect can be expected. Moreover, performing the oxidation treatment in a water-vapor atmosphere enables the amount of oxidation of the surface to increase. This enables the surface concentration to be significantly reduced. Furthermore, it is possible to control the removal region in the high concentration region of the outermost surface of the diffusion layer of the light receiving surface in accordance with the thickness of the oxide film formed by performing the thermal oxidation. Therefore, it is easy to control the in-plane uniformity and reproducibility in respective processes compared with the method of etching silicon with chemicals.

### BRIEF DESCRIPTION OF DRAWINGS

FIG. 1 is a diagram illustrating a solar cell according to the first embodiment, where FIG. 1(a) is a top view, FIG. 1(b) is a cross-sectional view taken along A-A, and FIG. 1(c) is an explanatory diagram illustrating the concentration profile of a diffusion layer on a light receiving surface.

FIG. 2 is a diagram illustrating a flowchart explaining the manufacturing process of the solar cell according to the first embodiment.

FIGS. 3(a) to 3(c) are process cross-sectional views explaining the manufacturing process of the solar cell according to the first embodiment.

FIGS. 4(a) to 4(c) are process cross-sectional views explaining the manufacturing process of the solar cell according to the first embodiment.

FIGS. 5(a) to 5(c) are process cross-sectional views explaining the manufacturing process of the solar cell according to the first embodiment.

FIG. 6 is a diagram illustrating a solar cell according to a second embodiment.

FIG. 7 is a diagram illustrating a flowchart explaining the manufacturing process of the solar cell according to the second embodiment.

FIGS. 8(a) to 8(c) are process cross-sectional views explaining the manufacturing process of the solar cell according to the second embodiment.

FIGS. 9(a) and 9(b) are process cross-sectional views explaining the manufacturing process of the solar cell according to the second embodiment.

FIG. 10 is a diagram illustrating a solar cell according to a third embodiment.

FIG. 11 is a diagram illustrating a flowchart explaining the manufacturing process of the solar cell according to the third embodiment.

FIGS. 12(a) to 12(c) are process cross-sectional views explaining the manufacturing process of the solar cell according to the third embodiment.

FIGS. 13(a) to 13(d) are process cross-sectional views explaining the manufacturing process of the solar cell according to the third embodiment.

FIG. 14 is a diagram illustrating a solar cell according to a fourth embodiment.

FIG. 15 is a diagram illustrating a flowchart explaining the manufacturing process of the solar cell according to the fourth embodiment.

FIGS. 16(a) to 16(c) are process cross-sectional views explaining the manufacturing process of the solar cell according to the fourth embodiment.

FIGS. 17(a) to 17(c) are process cross-sectional views explaining the manufacturing process of the solar cell according to the fourth embodiment.

### DESCRIPTION OF EMBODIMENTS

Exemplary embodiments of a manufacturing method of a solar cell and a solar cell according to the present invention will be explained below in detail with reference to the drawings. This invention is not limited to the embodiments and can be modified as appropriate without departing from the scope of the present invention. In the drawings explained below, for ease of understanding, the scales of respective layers or respective components may be shown differently from the scales in the actuality. This holds true for the relations between the drawings. Hatching is applied even to plan views in some cases in order to facilitate visualization of the drawings.

An explanation will be given of a selective-diffusion-layer forming step in the manufacturing method of a solar cell according to embodiments of the present invention. The embodiments that are considered here can include a case with a step of removing an oxide film that is formed during diffusion and/or a case with a step of removing an oxide film that is formed during thermal oxidation; therefore, four kinds of processes will be explained below as first to fourth embodiments.

In all the processes, in additional diffusion for forming a high-concentration layer in the collection-electrode forming region, the diffusion is performed while forming an oxide film. Consequently, an impurity is introduced into the oxide film from the diffusion layer by the diffusion in the region other than the collection-electrode forming region, thereby making the impurity concentration of the outermost surface lower than that of the surface portion. In the first, third, and fourth embodiments, an oxide film that contains an impurity and is formed during diffusion is removed. By removing the oxide film that contains an impurity and is formed during the diffusion in such a manner, the high-concentration region of the outermost surface can be easily introduced into an oxide film during the subsequent oxidation treatment. However, the surface concentration can be reduced without removing the oxide film containing an impurity by adjusting the diffusion condition and oxidation condition. The processing can be reduced by eliminating a removal step.

It is preferable in terms of passivation to leave the oxide film formed during thermal oxidation in place; however, the film thickness may increase more than necessary depending on the conditions. Thus, it is necessary to remove any oxide film that causes an optical problem. An explanation will be given below of each process.

### First Embodiment

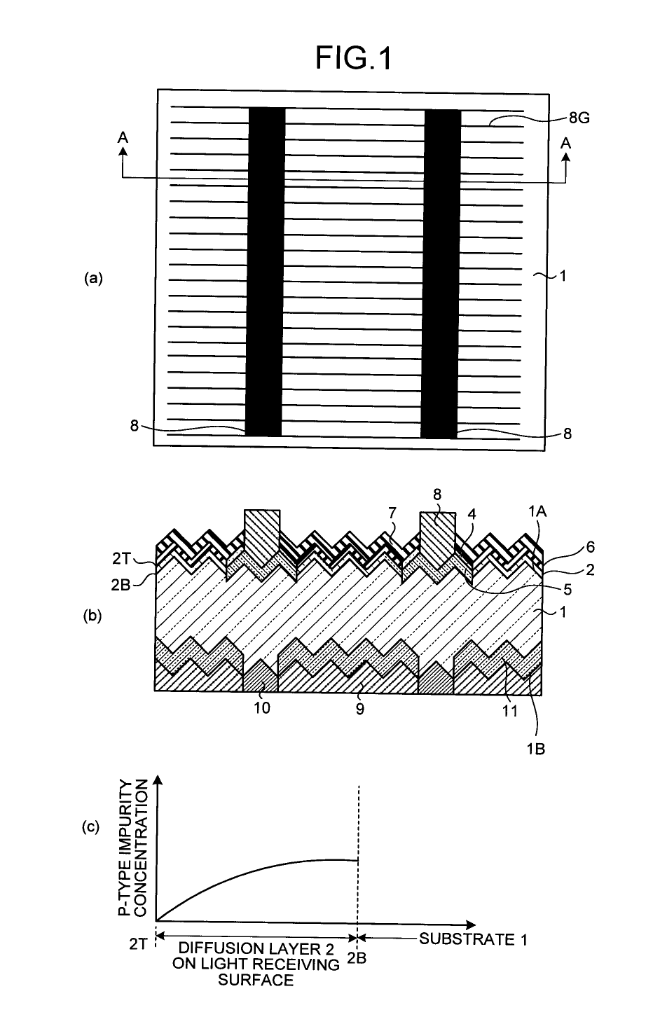

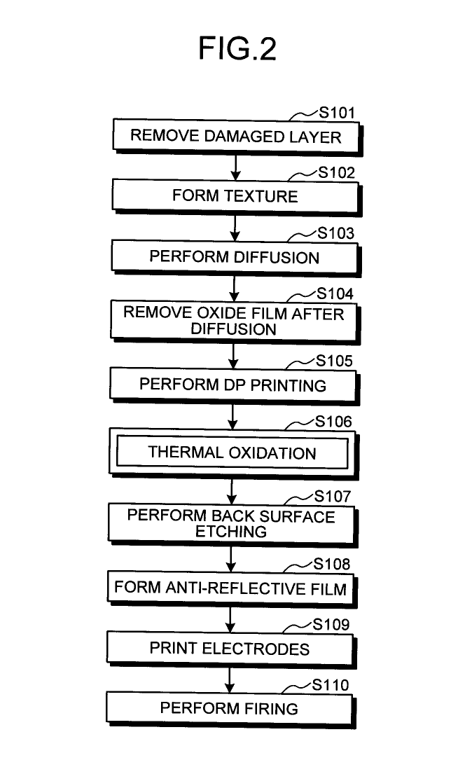

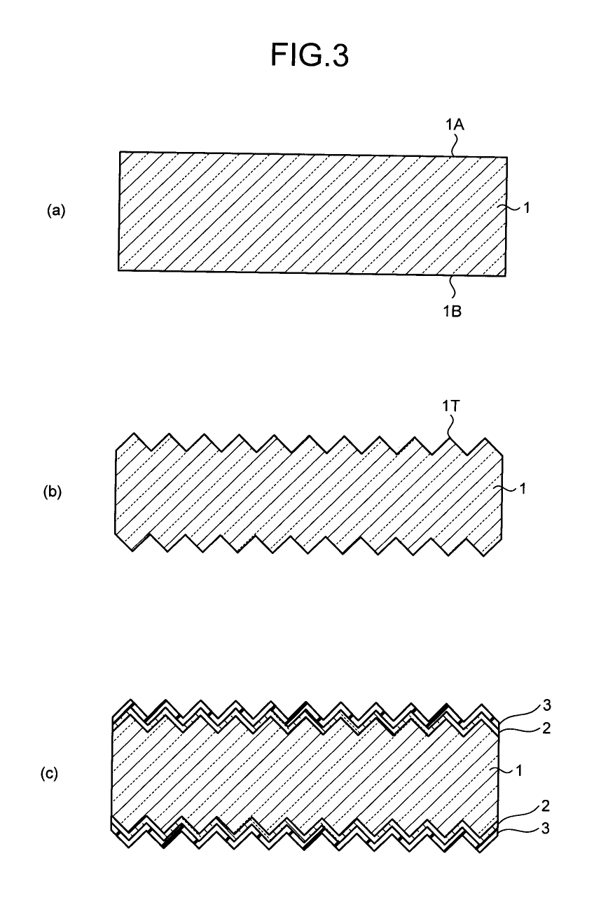

In the method according to a first embodiment, an explanation will be given of a case in which an oxide film that is formed during entire-surface diffusion, during which a diffusion layer is formed over the entire surface, is removed and a film that is formed during thermal oxidation for selective diffusion is left in place. FIG. 1 is a diagram illustrating a solar cell according to the first embodiment; where FIG. 1(a) is a top view; FIG. 1(b) is a cross-sectional view taken along A-A; and FIG. 1(c) is an explanatory diagram illustrating the concentration profile of a diffusion layer of the light receiving surface. FIG. 2 is a diagram illustrating a flowchart explaining the manufacturing process of the solar cell. FIGS. 3(a) to 3(c), FIGS. 4(a) to 4(c), and FIGS. 5(a) to 5(c) are process cross-sectional views illustrating the manufacturing process of the solar cell according to the first embodiment.

In the present embodiment, when a high-concentration diffusion layer 5 is formed in part of a first surface 1A of a substrate 1 in which a diffusion layer 2 of the light receiving surface is formed, the thermal oxidation is performed in a state where a diffusion source is formed, thereby introducing the impurity in the outermost surface of the diffusion layer 2 of the light receiving surface into a thermal oxide film 6. Consequently, as illustrated in the concentration profile of the diffusion layer of the light receiving surface in FIG. 1(c), an outermost surface 2T of the diffusion layer 2 of the light receiving surface has an impurity concentration lower than that on the inner side. An innermost surface 2B of the diffusion layer 2 has an impurity concentration higher than that of the outermost surface 2T. FIG. 1 illustrates first collection electrodes 8 formed on the light receiving surface side and grid electrodes 8G. In the present embodiment, there is no removal of the thermal oxide film 6 that is formed during the thermal oxidation that is performed in order to form the high-concentration diffusion layer 5 by thermally diffusing an impurity from a doping paste 4; therefore, the structure is such that residue of the doping paste 4 and the thermal oxide film 6 remain on the high-concentration diffusion layer 5 around the first collection electrodes 8 and thus the passivation effect is high.

An n-type single-crystal silicon substrate is used as the substrate 1. An n-type single-crystal silicon substrate is preferably used as an n-type crystal silicon substrate. This is because an n-type single crystal has fewer defects and thus high output characteristics for a solar cell can be expected. However, a polycrystalline silicon substrate may also be used for the substrate and a p-type substrate may also be used for the substrate. An n-type single-crystal silicon substrate is obtained by slicing a silicon ingot. Damage to the slices caused by the slicing is removed by etching the substrate, for example, with mixed acid of an aqueous hydrogen fluoride (HF) and nitric acid (HNO₃) or with an alkaline aqueous solution, such as NaOH. In such a manner, the damaged layer on the surface of the substrate 1 is removed (Step S101) and thus the substrate 1 is obtained such that it has the first surface 1A, which is the light receiving surface, and a second surface 1B opposed to the first surface as illustrated in FIG. 3(a).

Next, as illustrated in FIG. 3(b), a texture 1T is formed on the first and second surfaces 1A and 1B of the substrate 1 in order to reduce the reflectance (Step S102). Wet etching (anisotropic etching with alkali) is performed so as to obtain a random pyramid shape on the surface on the first surface 1A side, which is the light receiving surface of the substrate 1. The random pyramid shape has micro pyramids that are formed at random locations and have a base length of 100 nm to 30 μm. The etchant that is used is an alkaline fluid, such as NaOH, KOH, or tetramethylammonium hydroxide (TMAH), with an alcohol based additive, such as IPA, a surfactant, or a silicate compound, such as sodium orthosilicate, added thereto. The etching temperature is preferably 30° C. to 120° C. and the etching time is preferably 2 minutes to 60 minutes.

Next, as illustrated in FIG. 3(c), an impurity is diffused into the first and second surfaces 1A and 1B of the substrate 1 so as to form the diffusion layer 2 of the light receiving surface (Step S103). At this point of time, an oxide film 3 (doping glass) is formed on the surface. When the substrate 1 is of p-type, a donor, such as phosphorus, is used as the impurity. When the substrate 1 is of n-type, an acceptor, such as boron, is used as the impurity. The sheet resistance after the diffusion is 30 Ω/sq to 80 Ω/sq.

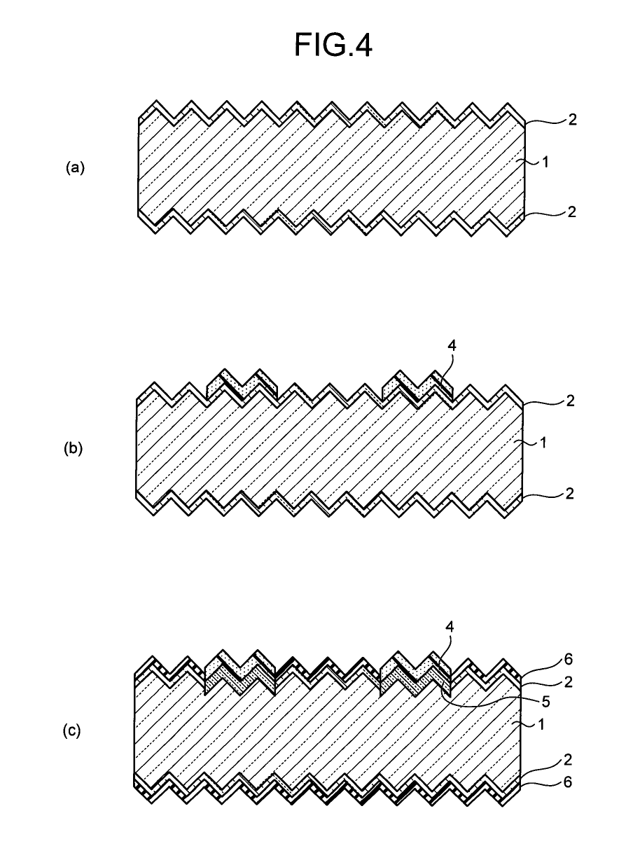

Next, as illustrated in FIG. 4(a), the oxide film 3 formed during the diffusion step is removed (Step S104).

Next, as illustrated in FIG. 4(b), the doping paste (DP) 4 is printed in the collection-electrode forming region by screen printing (Step S105). The doping paste 4 is a diffusion source for increasing the impurity concentration only in the electrode joining portion during the subsequent heat treatment. When a p-type substrate is used, a paste containing a donor is used. When an n-type substrate is used, a paste containing an acceptor is used.

Then, as illustrated in FIG. 4(c), the heat treatment is performed at 750 to 1000° C. in an oxidizing atmosphere (thermal oxidation: Step S106). The oxidation treatment can be performed in either a dry or wet ambient. In the thermal oxidation, an impurity is diffused into the portion of the substrate 1 under the doping paste 4 and thus the impurity concentration in the portion of the substrate 1 under the doping paste 4 becomes higher than that before the heat treatment, and the silicon outermost surface in other regions is oxidized. Consequently, the impurity in the outermost surface of the diffusion layer 2 of the light receiving surface excluding the high-concentration diffusion layer 5 is introduced into the thermal oxide film 6 and thus the impurity concentration is reduced.

The thermal oxide film 6 formed in the heat treatment may be used without being removed. In particular, when an n-type substrate is used and boron is diffused therein, the thermal oxide film 6 is preferably used as a passivation film.

With the above procedures, the diffusion layer 2 of the light receiving surface can be formed such that the electrode forming portion, i.e., the high-concentration diffusion layer 5, and the light-receiving-surface portion around the high-concentration diffusion layer 5 each have a suitable impurity concentration. Unlike the method of etching back the surface layer with a solution or the like, the surface layer to be etched is determined by the thermal oxidation; therefore, the in-plane distribution becomes uniform and the uniformity in respective processes improves. Thus, the solar cells can be reliably manufactured. Moreover, by regulating the treatment temperature, the treatment time period, and the gas flow rate during the diffusion step and the thermal oxidation step by using the process described above, it is possible to set the impurity concentration of the electrode forming portion, i.e., the high-concentration diffusion layer 5, and the diffusion layer 2 of the light receiving surface to a wide range.

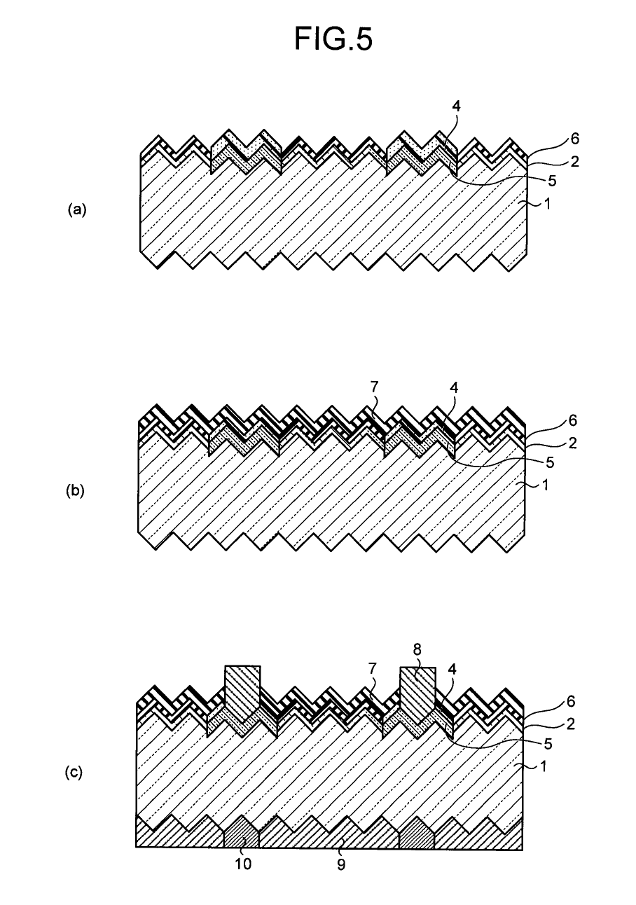

Next, as illustrated in FIG. 5(a), pn separation is performed by removing the diffusion layer 2 on the back surface (back surface etching: Step S107). Pn separation may be performed by using other methods.

Next, as illustrated in FIG. 5(b), an anti-reflective film 7 is formed (Step S108). Typical examples of the anti-reflective film 7 are SiN, TiO₂, and SiO and the anti-reflective film 7 is formed by a method, such as CVD, sputtering, or vapor deposition.

Next, as illustrated in FIG. 5(c), electrodes are printed (Step S109). A method using screen printing is typically used to form the first collection electrodes 8 made of Ag on the light receiving surface; form second collection electrodes 10, which are made of Ag and are used for attaching tabbing wires, on the back surface; and form Al electrodes 9 on the portion of the back surface other than the portion where the second collection electrodes 10 are formed. Then, firing is performed (Step S110) to form a contact and, at the same time, a BSF layer 11 is formed. Consequently, the solar cell illustrated in FIG. 1 is obtained.

The first embodiment has an effect in that the surface concentration can be significantly reduced in the thermal oxidation by removing the oxide film 3 formed during the diffusion. Moreover, if a film formed during the thermal oxidation is left in place, a high passivation effect can be obtained.

In the present embodiment, there is no removal of the thermal oxide film 6 that is formed during the thermal oxidation that is performed in order to form the high-concentration diffusion layer 5 by thermally diffusing an impurity from the doping paste 4; therefore, residue of the doping paste 4 and the thermal oxide film 6 remain even after the solar cell is formed. Because an etching step of removing the thermal oxide film 6 is not performed, the surface is not exposed to contamination. Therefore, the surface can be definitely maintained in a stable state.

### Second Embodiment

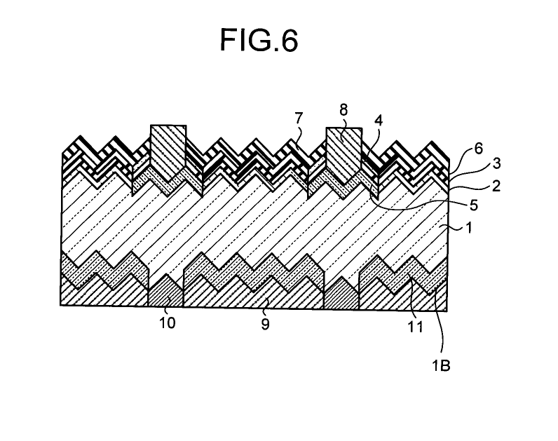

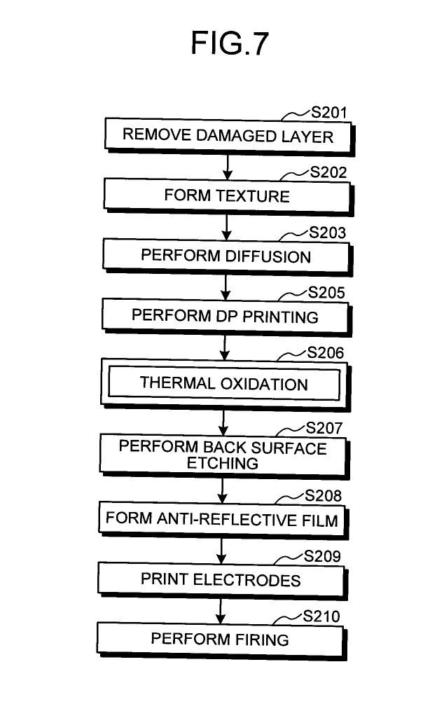

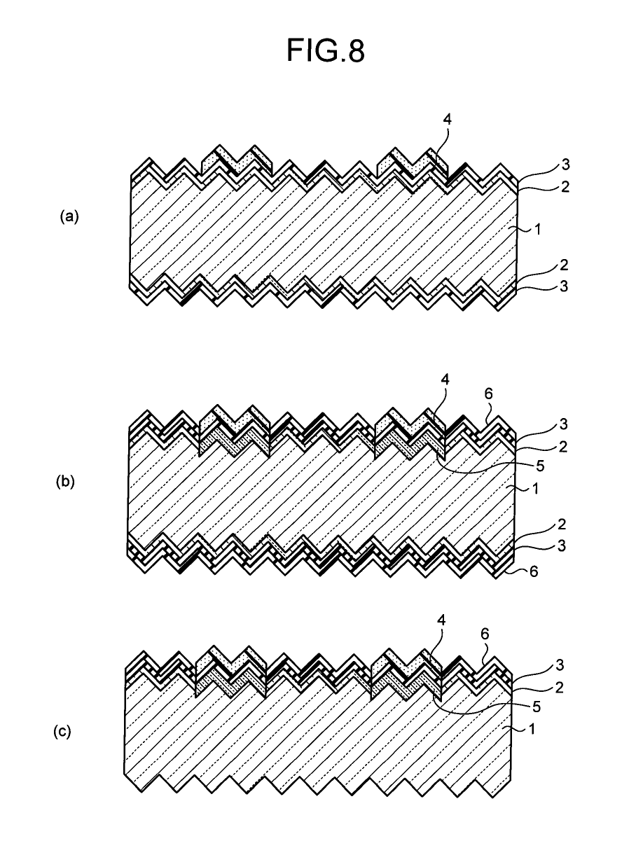

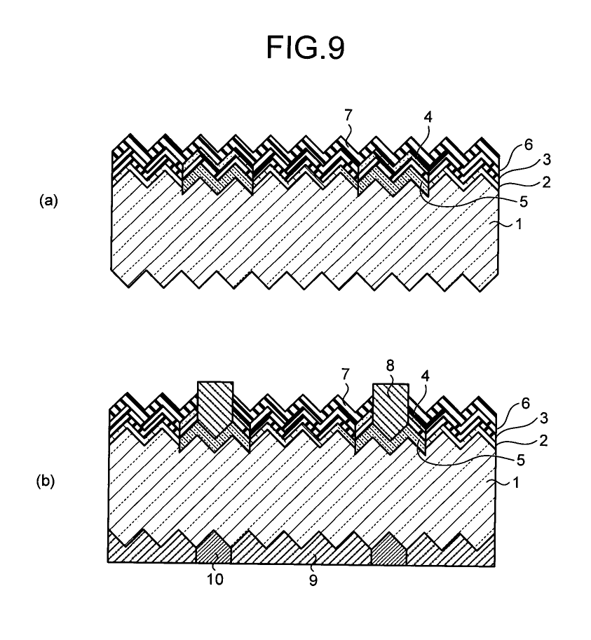

In the first embodiment, the doping paste 4 is formed after the oxide film 3 formed during the diffusion step (Step S103) is removed. In the present embodiment, the process is such that the oxide film 3 is left in place without being removed. In other words, the purpose of the present embodiment is to obtain a high passivation effect by leaving the oxide film 3 formed during the diffusion in place. FIG. 6 is a diagram illustrating a solar cell according to a second embodiment; FIG. 7 is a diagram illustrating a flowchart explaining the manufacturing process of the solar cell; and FIGS. 8(a) to 8(c) and FIGS. 9(a) and 9(b) are process cross-sectional views. As illustrated in FIG. 6, the solar cell in the present embodiment is the same as the solar cell in the first embodiment illustrated in FIG. 1 except for the point that the oxide film 3 is left on the light receiving surface side. Thus, the same portions are denoted by the same reference numerals and an explanation thereof is omitted here. In a similar manner to the first embodiment, in the present embodiment, there is no removal of the thermal oxide film 6 that is formed during the thermal oxidation that is performed in order to form the high-concentration diffusion layer 5 by thermally diffusing an impurity from the doping paste 4; therefore, the structure is such that residue of the doping paste 4 and the thermal oxide film 6 remain on the high-concentration diffusion layer 5 around the first collection electrodes 8 and thus the passivation effect is high.

Next, an explanation will be given of the manufacturing process of the solar cell according to the second embodiment. The damaged layer removal (Step S201), the texture formation (Step S202), and the diffusion (Step S203) step are completely the same as the damaged layer removal (Step S101), the texture formation (Step S102), and the diffusion (Step S103) step illustrated in FIGS. 3(a) to 3(c) in the first embodiment. Therefore, they are not illustrated here.

In the first embodiment, the oxide film removal step S104 of removing the oxide film 3 is performed after the diffusion step S103. In the present embodiment, the flowchart proceeds to the step of printing the doping paste 4 (Step S205) without performing the oxide film removal step of removing the oxide film 3, i.e., with the oxide film 3 being left in place.

Specifically, in a similar manner to that illustrated in FIG. 1(c), an impurity is diffused into the first and second surfaces 1A and 18 of the substrate 1 so as to form the diffusion layer 2 of the light receiving surface (Step S203). At this point of time, the oxide film 3 (doping glass) is formed on the surface. In the present embodiment, the oxide film 3 is left in place.

Next, as illustrated in FIG. 8(a), the doping paste (DP) 4 is printed, by screen printing, in the collection-electrode forming region of the upper layer of the oxide film 3 that is formed during the diffusion step and is left in place without being removed (Step S205). The doping paste 4 is a diffusion source for increasing the impurity concentration only in the electrode joining portion during the subsequent heat treatment. Other portions are similar to those in the first embodiment.

Then, as illustrated in FIG. 8(b), the heat treatment is performed at 750 to 1000° C. in an oxidizing atmosphere (thermal oxidation: Step S206). The oxidation treatment can be performed in either a dry or wet ambient. In the thermal oxidation, an impurity is diffused into the portion of the substrate 1 under the doping paste 4 and thus the impurity concentration in the portion of the substrate 1 under the doping paste 4 becomes higher than that before the heat treatment, and the silicon outermost surface in other regions is slightly oxidized. Consequently, the impurity in the outermost surface of the diffusion layer 2 of the light receiving surface is introduced into the oxide film 3 and thus the impurity concentration is reduced. The thickness of the oxide film 3 is slightly increased.

The thermal oxide film 6 formed in the heat treatment may be used without being removed. In particular, when the n-type substrate 1 is used and boron is diffused therein, the oxide film is preferably used as a passivation film.

Next, as illustrated in FIG. 8(c), pn separation is performed by removing the diffusion layer 2 on the back surface (back surface etching: Step S207). Pn separation may be performed by using other methods.

Next, as illustrated in FIG. 9(a), the anti-reflective film 7 is formed (Step S208). Typical examples of the anti-reflective film 7 are SiN, TiO₂, and SiO and the anti-reflective film 7 is formed by a method, such as CVD, sputtering, or vapor deposition.

Next, as illustrated in FIG. 9(b), electrodes are printed (Step S209). A method using screen printing is typically used to form the first collection electrodes 8 made of Ag on the light receiving surface side; form Ag electrodes for attaching tabbing wires as the second collection electrodes 10 on the back surface side; and form the Al electrodes 9 on the portion of the back surface other than the portion where the Ag electrodes are formed. Then, firing is performed (Step S210) to form a contact and, at the same time, the BSF layer 11 is formed. Consequently, the solar cell illustrated in FIG. 6 is obtained.

In the second embodiment, the oxide film 3 formed during the diffusion is left in place without being removed; therefore, the oxide film 3 and the thermal oxide film 6 remain around the first collection electrodes 8 and thus a high passivation effect can be obtained. In other words, the oxide film 3 and the thermal oxide film 6 function as a passivation film.

As described above, in the present embodiment, in addition to the oxide film 3 formed during the diffusion not being removed, the thermal oxide film 6 is also not removed that is formed during the thermal oxidation that is performed in order to form the high-concentration diffusion layer 5 by thermally diffusing an impurity from the doping paste 4; therefore, residue of the doping paste 4 and the thermal oxide film 6 remain even after the solar cell is formed. Because an etching step of removing the thermal oxide film 6 is not performed, the surface is not exposed to contamination. Therefore, the surface can be definitely maintained in a stable state.

### Third Embodiment

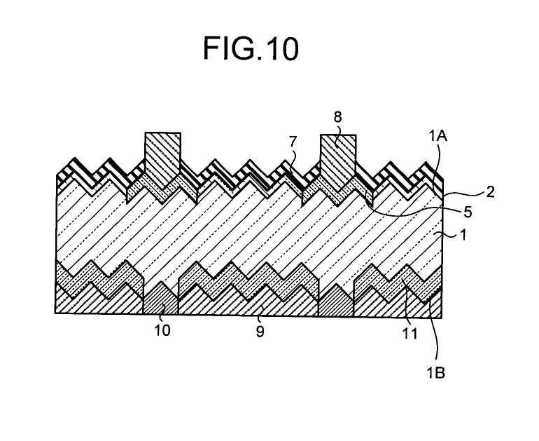

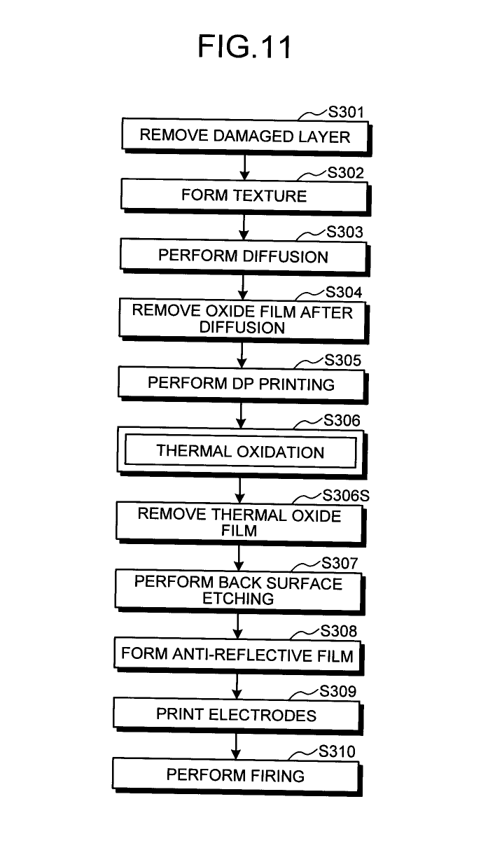

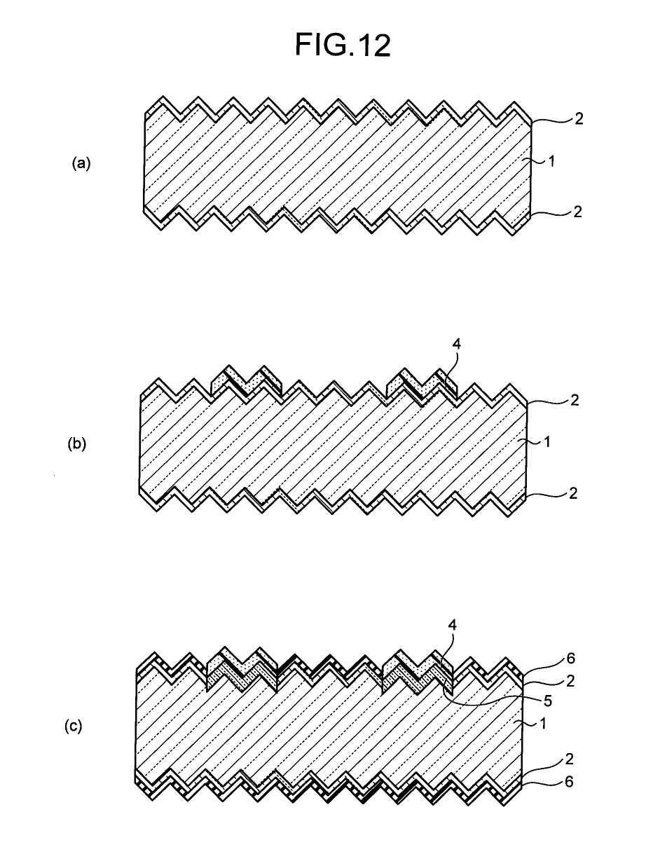

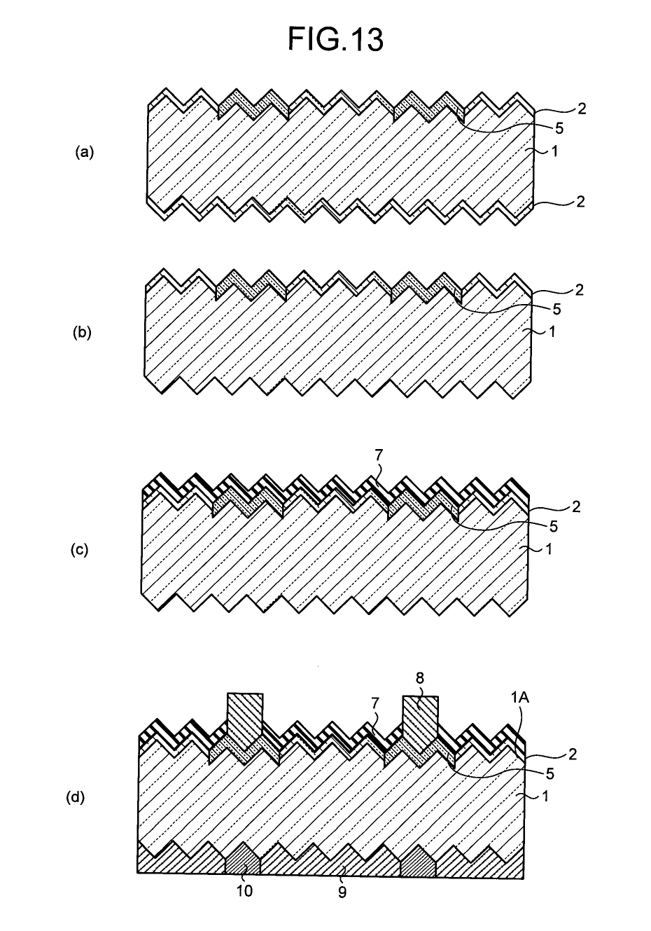

In the first embodiment, the back surface etching (S107) and the anti-reflective film forming step (S108) are performed in a state where the thermal oxide film 6 formed during the thermal oxidation step (Step S106) is left in place without being removed. In the present embodiment, a case will be explained in which the oxide film 3 formed during the diffusion is removed and a film formed during the thermal oxidation, i.e., the thermal oxide film 6, is also removed. This means that neither of the oxide film 3 nor the thermal oxide film 6 is left in place. FIG. 10 is a diagram illustrating a solar cell according to a third embodiment; FIG. 11 is a diagram illustrating a flowchart explaining the manufacturing process of the solar cell; and FIGS. 12(a) to 12(c) and FIGS. 13(a) to 13(d) are process cross-sectional views. The solar cell in the present embodiment is the same as the solar cell in the first embodiment illustrated in FIG. 1 except for the point that the thermal oxide film 6 is not left on the light receiving surface side. Thus, the same portions are denoted by the same reference numerals and an explanation thereof is omitted here.

Next, an explanation will be given of the manufacturing process of the solar cell according to the third embodiment. The damaged layer removal (Step S301), the texture formation (Step S302), the diffusion (Step S303) step, the oxide film removal (Step S304), the doping paste printing (Step S305), and the thermal oxidation (Step S306) are completely the same as the damaged layer removal (Step S101), the texture formation (Step S102), the diffusion (Step S103) step, the oxide film removal (Step S104), the doping paste formation (Step S105), and the thermal oxidation (Step S106) in the first embodiment.

After the damaged layer removal (Step S301), the texture formation (Step S302), and the diffusion (Step S303) are performed as illustrated in FIGS. 3(a) to 3(c), the oxide film removal (Step S304) as illustrated in FIG. 12(a), the doping paste printing (Step S305) as illustrated in FIG. 12(b), and the thermal oxidation (Step S306) as illustrated in FIG. 12(c) are performed. Then, after the thermal oxidation (Step S306), the thermal oxide film 6 is removed as illustrated in FIG. 13(a) (Step S306S). If the thermal oxide film 6 is too thick, it may pose an optical problem. Thus, removing the thermal oxide film 6 improves the optical characteristics. Additional film formation may be performed in order to improve the passivation properties.

Next, as illustrated in FIG. 13(b), pn separation is performed by removing the diffusion layer 2 on the back surface (back surface etching: Step S307). Pn separation may be performed by using other methods.

Next, as illustrated in FIG. 13(c), the anti-reflective film 7 is formed (Step S308). Typical examples of the anti-reflective film 7 are SiN, TiO₂, and SiO and the anti-reflective film 7 is formed by a method, such as CVD, sputtering, or vapor deposition.

Next, as illustrated in FIG. 13(d), electrodes are printed (Step S309). A method using screen printing is typically used to form the first collection electrodes 8 made of Ag on the light receiving surface; form the second collection electrodes 10, which are made of Ag and are used for attaching tabbing wires, on the back surface; and form the Al electrodes 9 on the portion of the back surface other than the portion where the second collection electrodes 10 are formed. Then, firing is performed (Step 5310) to form a contact and, at the same time, the BSF layer 11 is formed. Consequently, the solar cell illustrated in FIG. 10 is obtained.

The present embodiment has an effect in that the surface concentration can be significantly reduced in the thermal oxidation by removing the oxide film 3 formed during the diffusion. Moreover, if the thermal oxide film 6 is thick, it may cause a large optical loss. Thus, removing the thermal oxide film 6 can reduce the optical loss.

### Fourth Embodiment

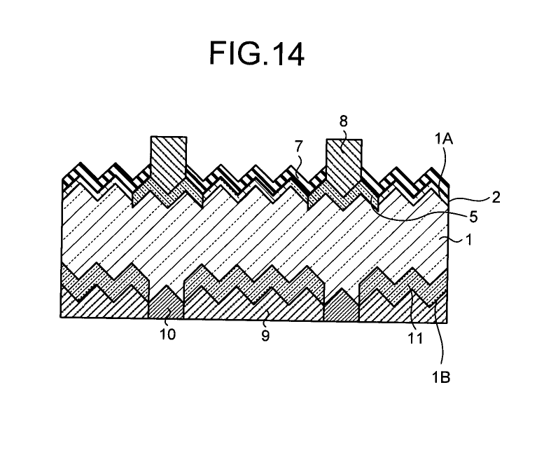

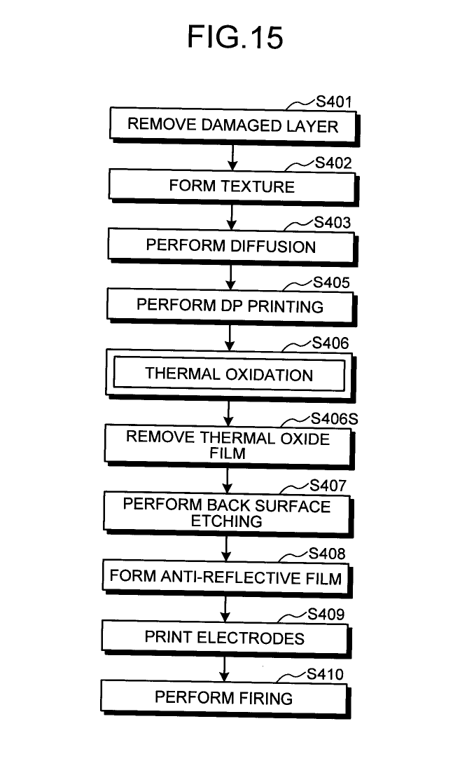

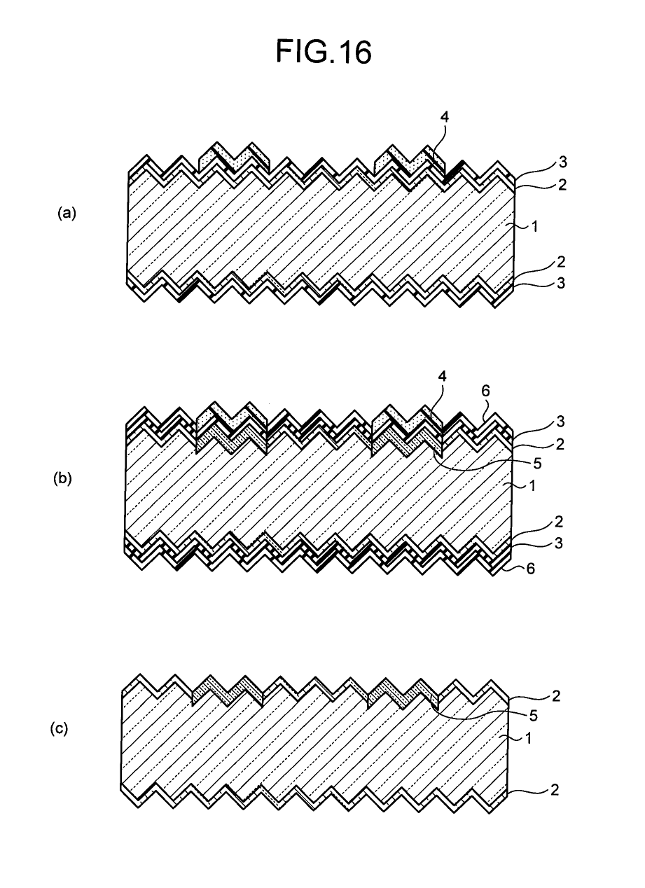

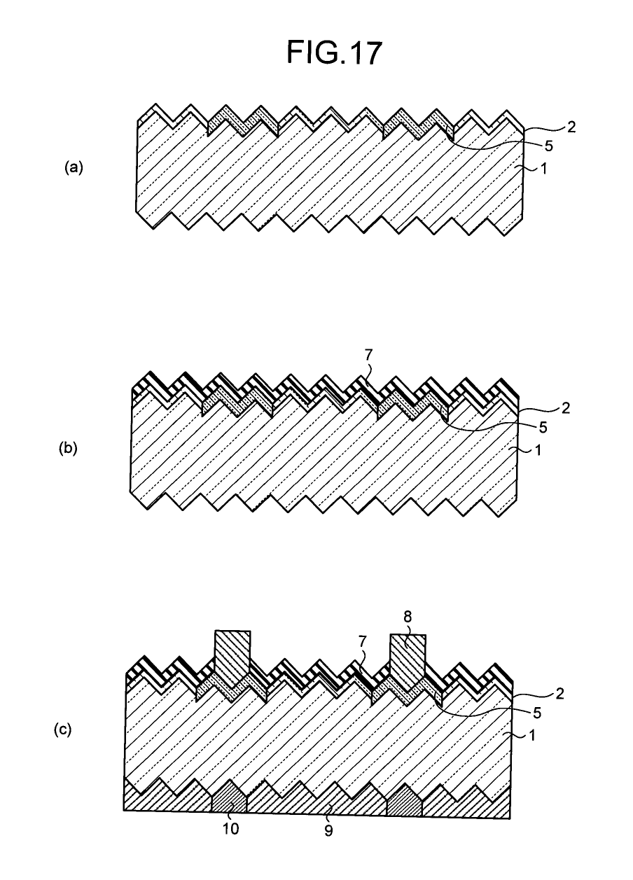

In the second embodiment, the oxide film 3 formed during the diffusion and a film formed during the thermal oxidation, i.e., the thermal oxide film 6, are left in place without being removed. In the present embodiment, an explanation will be given of a case where the oxide film 3 formed during the diffusion is left in place without being removed but the thermal oxide film 6 is removed. FIG. 14 is a diagram illustrating a solar cell according to a fourth embodiment; FIG. 15 is a diagram illustrating a flowchart explaining the manufacturing process of the solar cell; and FIGS. 16(a) to 16(c) and FIGS. 17(a) to 17(c) are process cross-sectional views. The solar cell in the present embodiment is the same as the solar cell in the second embodiment illustrated in FIG. 6 except for the point that the thermal oxide film 6 is not left on the light receiving surface side. Thus, the same portions are denoted by the same reference numerals and an explanation thereof is omitted here.

Next, an explanation will be given of the manufacturing process of the solar cell according to the fourth embodiment. The damaged layer removal (Step S401), the texture formation (Step S402), the diffusion (Step S403) step, the doping paste printing (Step S405), and the thermal oxidation (Step S406) are completely the same as the damaged layer removal (Step S201), the texture formation (Step S202), the diffusion (Step S203) step, the doping paste printing (Step S205), and the thermal oxidation (Step S206) in the second embodiment.

After the doping paste printing (Step S405) is performed as illustrated in FIG. 16(a), as illustrated in FIG. 16(b), the heat treatment is performed at 750 to 1000° C. in an oxidizing atmosphere (thermal oxidation step S306). The oxidation treatment can be performed in either a dry or wet ambient. As illustrated in FIG. 16(c), an impurity is diffused into the portion of the substrate 1 under the doping paste 4 and thus the impurity concentration in the portion of the substrate 1 under the doping paste 4 becomes higher than that before the heat treatment, and the outermost surface in other regions of the substrate 1 is oxidized. Consequently, the high-concentration impurity region is introduced into the oxide film 3 and the thermal oxide film 6 and thus the impurity concentration is reduced.

After the thermal oxidation (Step S406), the thermal oxide film 6 is removed as illustrated in FIG. 16(c) (Step S406S). If the thermal oxide film 6 is too thick, it may pose an optical problem. Thus, removing the thermal oxide film 6 improves the optical characteristics. Additional film formation may be performed in order to improve the passivation properties.

Next, as illustrated in FIG. 17(a), pn separation is performed by removing the diffusion layer 2 on the back surface (back surface etching: Step S407). Pn separation may be performed by using other methods.

Next, as illustrated in FIG. 17(b), the anti-reflective film 7 is formed (Step S408). Typical examples of the anti-reflective film 7 are SiN, TiO₂, and SiO and the anti-reflective film 7 is formed by a method, such as CVD, sputtering, or vapor deposition.

Next, as illustrated in FIG. 17(c), electrodes are printed (Step S409). A method using screen printing is typically used to form the first collection electrodes 8 made of Ag on the light receiving surface; form the second collection electrodes 10, which are made of Ag and are used for attaching tabbing wires, on the back surface; and form the Al electrodes 9 on the portion of the back surface other than the portion where the second collection electrodes 10 are formed. Then, firing is performed (Step S410) to form a contact and, at the same time, the BSF layer 11 is formed. Consequently, the solar cell illustrated in FIG. 14 is obtained.

In the fourth embodiment, the oxide film 3 formed during the diffusion is not removed; therefore, the step of removing the oxide film 3 can be omitted. The thermal oxide film 6 functions as a passivation film. Furthermore, if the thermal oxide film 6 is thick, the optical loss can be reduced by removing the thermal oxide film 6.

Moreover, after an impurity is diffused, a doping paste is printed and then thermal oxidation is performed, which are common to the first to fourth embodiments. Therefore, an effect is obtained where the impurity concentration can be reduced in the light-receiving-surface region of the silicon surface and the impurity concentration can be increased in the region of the silicon surface under the electrodes.

As described above, the use of the methods described in the first to fourth embodiments enables, without significantly increasing man-hours, a selective emitter structure to be formed and thus enables the solar cells to have a high efficiency. Moreover, the methods described in the first to fourth embodiments can be incorporated in the conventional manufacturing processes, and this contributes to the solar cells having uniform characteristics when they are mass produced.

Some embodiments of the present invention have been described. However, these embodiments are presented as examples and are not intended to limit the scope of the invention. These novel embodiments can be implemented in other various forms, and various omissions, replacements, and changes can be made without departing from the spirit of the present invention. These embodiments and their modifications are included in the scope and spirit of the present invention and are also included in the invention described in the claims and its equivalents.

### REFERENCE SIGNS LIST

1 substrate, 2 diffusion layer, 3 oxide film, doping paste, 5 high-concentration diffusion layer, 6 thermal oxide film, 7 anti-reflective film, 8 first collection electrode, 9 Al electrode, 10 second collection electrode, 11 BSF layer.

1. A manufacturing method of a solar cell comprising:
a step of preparing a first-conductivity-type semiconductor substrate that includes a first surface constituting a light receiving surface and a second surface opposed to the first surface;
a first diffusion step of forming a second-conductivity-type diffusion layer in the first surface;
a second step of forming a film that includes a second-conductivity-type diffusion source on part of the first surface of the semiconductor substrate in which the second-conductivity-type diffusion layer is formed;
a third step of forming a high-concentration diffusion layer by diffusion from the diffusion source and forming an oxide film, by performing a heat treatment in an oxidizing atmosphere on the semiconductor substrate on which the diffusion source is formed;
a step of forming a first electrode on the high-concentration diffusion layer; and
a step of forming a second electrode on the second surface.

2. The manufacturing method of a solar cell according to claim 1, wherein the third step includes a step of performing a heat treatment in a water-vapor atmosphere.

3. The manufacturing method of a solar cell according to claim 1, further comprising, after the first diffusion step and before the second step, a step of removing an oxide film generated in the first diffusion step.

4. The manufacturing method of a solar cell according to claim 1, further comprising, before the step of forming the first electrode, a step of removing a thermal oxide film generated in the third step.

5. A solar cell comprising:
a first-conductivity-type semiconductor substrate that includes a first surface constituting a light receiving surface and a second surface opposed to the first surface;
a second-conductivity-type diffusion layer formed in the first surface;
a high-concentration diffusion layer formed in part of the first surface of the semiconductor substrate in which the second-conductivity-type diffusion layer is formed;
a first electrode formed on the high-concentration diffusion layer; and
a second electrode formed on the second surface, wherein
the second-conductivity-type diffusion layer exposed from the high-concentration diffusion layer of the first surface includes a low-concentration layer in an outermost surface, the low-concentration layer having a lower impurity concentration than an impurity concentration on an inner side of the second-conductivity-type diffusion layer.

6. The solar cell according to claim 5, wherein a region of the first surface that is other than a portion on which the first electrode is formed is covered with a passivation film.

7. The solar cell according to claim 6, wherein the passivation film is a thermal oxide film containing an impurity that is same as an impurity in the diffusion layer.
